(19) United States
(12) Patent Application Publication
(10) Pub. No.: US 2024/0235286 A1
(43) Pub. Date: Jul. 11, 2024

(54) SINGLE WINDING HYBRID EXCITATION MAGNETIC FIELD MODULATION MOTOR AND SYNERGY EXCITATION DESIGN METHOD THEREOF

(71) Applicant: JIANGSU UNIVERSITY, Zhenjiang (CN)

(72) Inventors: Liang XU, Zhenjiang (CN); Lele CHANG, Zhenjiang (CN); Tingting JIANG, Zhenjiang (CN); Wenxiang ZHAO, Zhenjiang (CN)

(73) Assignee: JIANGSU UNIVERSITY, Zhenjiang (CN)

(21) Appl. No.: 18/008,452

(22) PCT Filed: May 12, 2022
(86) PCT No.: PCT/CN2022/092335

§ 371 Date: Dec. 6, 2022

(30) Foreign Application Priority Data
Mar. 16, 2022 (CN) 202210257690.3

(51) Int. Cl. H02K 1/17; H02K 1/16; H02K 3/28; H02K 15/02

(52) U.S. Cl. CPC H02K 1/17; H02K 1/165; H02K 3/28; H02K 15/02; H02K 2213/03

(57) ABSTRACT

A single winding hybrid excitation magnetic field modulation motor includes a stator, a rotor, a winding and a permanent magnet. The stator includes a stator iron core, a permanent magnet and a winding. The stator iron core includes stator teeth and stator yoke. Each stator tooth is split into an equal number of split teeth facing the air gap side. All permanent magnets are embedded in the grooves between the split teeth on the same stator tooth, the polarity of all permanent magnets located on the same stator tooth is the same, and the polarity of the permanent magnets on the adjacent stator teeth is opposite. A single non-overlapping concentrated winding is wound on all stator teeth, and DC current and AC current are simultaneously passed into each set of windings, in which field winding and permanent magnet are excited together to form hybrid excitation.

### CROSS REFERENCE TO THE RELATED APPLICATIONS

This application is the national phase entry of International Application No. PCT/CN2022/092335, filed on May 12, 2022, which is based upon and claims priority to Chinese Patent Application No. 202210257690.3, filed on Mar. 16, 2022, the entire contents of which are incorporated herein by reference.

### TECHNICAL FIELD

The present disclosure relates to a single winding hybrid excitation motor and a synergy excitation design method thereof, and in particular, to a single winding hybrid excitation magnetic field modulation motor with high torque density and wide flux regulation ability.

### BACKGROUND

Hybrid excitation motor combines the advantages of electric excitation motor and permanent magnet motor. It has the characteristics of regulate magnetic field, large torque density and wide high efficiency area. Therefore, it has important research value and broad application prospects in the fields of wind power generation and electric vehicles.

Chinese invention patent application No. 201510474238.2 discloses a hybrid excitation motor. The armature winding and field winding are placed on the stator side, avoiding brushes and slip rings, and the motor has high reliability. However, there is space competition between armature and field windings in the stator slot, which greatly limits the improvement of torque. In order to further increase the reliability of the motor, Chinese invention patent application No. 201910281738.2 discloses a long permeance doubly salient motor. The design scheme of the motor places two sets of windings and permanent magnets on the stator side, which is conducive to the unified management of the temperature of the excitation source and avoid the problem of local overheating of the excitation source; The rotor structure is simple and only salient pole structure, which improves the reliability of the moving part. In order to alleviate the competition conflict in stator space, a long magnetic guide tooth is designed to reduce the influence of the size of permanent magnet and field winding on armature winding. The design effectively improves the slot area of armature and field windings, so that the motor has high output torque and magnetic regulation ability. Although this scheme alleviates the space conflict caused by two sets of windings in the stator through the design of magnetic guide teeth, it can not fundamentally solve the problem of limited winding slot area. In addition, the stator structure of this scheme is complex, which increases the difficulty of motor processing, and the problem of difficult offline of two sets of windings also arises. Chinese invention patent application No. 202011475772.2 discloses a multi-objective optimization method for optimizing the hybrid excitation motor. The intelligent optimization algorithm is combined with the independent optimization of individual parameters to optimize the parameters of the motor, such as core pole arc, air gap length, stator yoke width, slot pole arc and so on, so as to improve the output torque and magnetic regulation ability of the motor. However, this method does not specifically design the pole slot matching and dual excitation source of the motor, which can not provide theoretical guidance for the optimal design of the motor. And this method needs to use the finite element method to fit the design variables and design objectives, which has high computational complexity and long optimization time.

To sum up, for the hybrid excitation motor, using the magnetic field modulation principle can effectively improve the motor performance, but how to combine the armature winding and field winding into one to form a single winding structure to solve the spatial conflict between the two sets of windings is an important means to further improve the motor performance. In addition, in order to further improve the performance of the motor, we need to start from the two sources of magnetomotive force, carry out cooperative design on them, optimize the pole slot fit and key structural parameters, so as to design a dual excitation topology motor with high torque density and wide flux regulation ability. Finally, with the improvement of flux regulation ability, the parallel flux path design of two excitation sources is also a necessary technical means to avoid the threat of field winding excitation magnetic field to permanent magnet irreversible demagnetization.

### SUMMARY

The purpose of the present disclosure is to propose a single winding hybrid excitation magnetic field modulation motor and a hybrid excitation design method thereof in view of the shortcomings of the existing hybrid excitation motor. The armature winding and field winding are combined into one by adopting the single winding design, so as to eliminate the space competition of two sets of windings in the hybrid excitation motor; the stator adopts the split tooth structure and the permanent magnet is embedded in the groove between the split teeth. The design method of field winding and PM hybrid excitation is established. The formulas of back-EMF excited by permanent magnet and field winding excitation under different pole slot coordination are deduced, and the optimal pole slot coordination is determined; on this basis, by analyzing the influence of permanent magnet arc and split tooth arc on permanent magnet magnetomotive force and field winding magnetomotive force, the optimal selection area of two pole arcs is obtained to improve the utilization efficiency of hybrid excitation magnetic field, so as to effectively enhance the torque density and flux regulation ability of single winding hybrid excitation magnetic field modulation motor. At the same time, the flux paths excited by permanent and field winding excitations are independent of each other, which reduces the risk of irreversible demagnetization of the permanent magnet.

Specifically, the motor of the present disclosure adopts the following technical scheme: a single winding hybrid excitation magnetic field modulation motor comprises a stator and a rotor (1), the stator comprises a stator core, a permanent magnet (6) and a winding, wherein the stator core is composed of Nₛ stator teeth (3) and a stator yoke (2); each stator tooth (3) is split into any equal number of n split teeth (5) facing the air gap side and n>1, the permanent magnet (6) is embedded in the groove between the split teeth on the same stator tooth, each permanent magnet (6) is clamped by two split teeth (5) on the same stator tooth, the number of permanent magnets (6) on each stator tooth is n−1, and the polarity of permanent magnets (6) on the same stator tooth (3) is the same; the polarity of permanent magnets (6) on two adjacent stator teeth (3) is opposite, the total number Nₚₘ of permanent magnets (6) in the motor is (n−1) Nₛ, and the total number of split teeth (5) is nNₛ; all stator teeth are wound with a single non overlapping concentrated winding; each set of winding is connected with DC current and AC current at the same time, in which field winding and permanent magnets (6) are excited together to form hybrid excitation; the amplitude of DC current in all windings is equal, and the flow direction of DC current is determined according to the magnetic field in the opposite direction of DC current in adjacent windings, so as to generate effective field winding excitation magnetic field and form effective hybrid excitation with permanent magnets (6); the rotor part is composed of rotor yoke and salient poles, and the number of salient poles is nNₛ+m; wherein m is any natural number.

Further, the winding is connected into two groups of three-phase windings, which are respectively controlled by two three-phase inverter circuits; the field winding and permanent magnet (6) forms a hybrid excitation magnetic field to provide excitation for the motor, while the three-phase AC current in the winding generates a rotating magnetic field and interacts with the excitation magnetic field to produce continuous torque; the winding wound on the stator teeth with the same polarity permanent magnet (6) forms a group of three-phase windings, and the winding wound on the stator teeth with another permanent magnet (6) with the same polarity forms a second group of three-phase windings; the excitation magnetic field generated by DC current and the permanent magnet magnetic field generated by permanent magnet act together to produce hybrid excitation effect; the DC current of the two groups of three-phase windings is the same, and the flow direction of the DC current is determined according to the magnetic field in the opposite direction of the DC current in the adjacent windings; the excitation magnetic field formed by the two groups of three-phase windings is flux enhancing effect when it is the same as the magnetic field direction of the permanent magnet on each stator tooth, and is flux weakening effect when it is opposite to the magnetic field direction of the permanent magnet on each stator tooth.

Further, when m is an odd number, the two groups of three-phase windings are connected in a star-shaped connection and the neutral points are connected, and the control the current on the neutral point to adjust the DC current to control the field winding excitation magnetic field; when m is an even number, the two groups of three-phase windings are connected in a star connection but the neutral point is connected or the two groups of three-phase windings are connected in a delta connection; control the DC current in each set of windings to control the field winding excitation magnetic field.

Further, the motor structure can be an inner rotor structure or an outer rotor structure.

The disclosure relates to a single winding hybrid excitation magnetic field modulation motor synergy excitation design method, including the following steps:

step 1, firstly, Based on the theory of magnetic field modulation, back-EMF E_{cpm} excited by permanent magnet and back-EMF E_{cdc} excited by field winding are derived when the number of split teeth n and the number of rotor salient poles are both changed; by comparing the calculation results of back-EMF E_{cpm} excited by permanent magnet and back-EMF E_{cdc} excited by field winding, the optimal number of rotor salient poles with the best back-EMF E_{cpm} excited by permanent magnet and back-EMF E_{cdc} excited by field winding is obtained for each split tooth number.

step 2, then on the basis of determining the optimal number of split teeth n and the number of rotor salient poles, the effects of the pole arc of permanent magnet θₚₘ and split tooth arc θₜₚ on the permanent magnet excitation effective magnetomotive force ΣFₚₘ and effective field winding excitation magnetomotive force ΣF_{dc} are deduced; thus, the optimal selection region of the two pole arc parameters of the motor is obtained under the determination of the number of split teeth n and the number of rotor salient poles.

Further, the specific process of step 1 is as follows:

Step 1.1: according to the size parameters of the stator part, calculate the permanent magnetomotive force and field winding magnetomotive force when different stator split teeth n, and the permanent magnet magnetomotive force Fₚₘ(n,θ) and field winding magnetomotive force F_{dc}(n,θ) expressed as follows:

$$\{ \begin{matrix}{F}_{p m} ( n , θ ) = {\sum }_{i = 1 , 3 , 5 …}^{∞} {F}_{p m}^{{n}_{i}} sin ( i \frac{{N}_{s}}{2} θ ) \\ {F}_{d c} ( n , θ ) = {\sum }_{k = 1 , 3 , 5 …}^{∞} {F}_{d c}^{{n}_{k}} sin ( k \frac{{N}_{s}}{2} θ )\end{matrix}$$

where, Nₛ is the number of stator teeth, i, k are positive integers, θ is the rotor position angle, Fₚₘⁿ^{ᵢ} is the i^{th} order amplitude component of permanent magnet magnetomotive force and F_{dc}ⁿ^{ₖ} is the k^{th} order amplitude component of field winding magnetomotive force; according to the parity of the number of split teeth n, Fₚₘⁿ^{ᵢ} and F_{dc}ⁿ^{ₖ} have different expressions; when n is an odd number, they can be expressed as:

$$\{ \begin{matrix}{F}_{p m}^{{n}_{i}} = {( - 1 )}^{( i - 1 ) / 2} \frac{{2}^{( n + 3 ) / 2} {F}_{1}}{π i} sin ( i \frac{{N}_{s} {θ}_{pm}}{4} ) \times \\ {\prod }_{z = 1 , 2 , 3 …}^{( n - 1 ) / 2} cos [ i \frac{z {N}_{s} ( {θ}_{p m} + {θ}_{tp} )}{4} ] \\ {F}_{d c}^{{n}_{k}} = {( - 1 )}^{( k + 1 ) / 2} \frac{4 {F}_{2}}{π k} sin ( k \frac{{N}_{s} {θ}_{tp}}{4} ) \times \\ \{ 1 + {\sum }_{z = 1 , 2 , 3 …}^{( n - 1 ) / 2} 2 cos [ k \frac{z {N}_{s} ( {θ}_{pm} + {θ}_{tp} )}{2} ] \}\end{matrix}$$

where the pole arc of permanent magnet is denoted as θₚₘ, and the split tooth arc is denoted as θₜₚ. when n is an even number, they can be expressed as:

$$\{ \begin{matrix}{F}_{p m}^{{n}_{i}} = {( - 1 )}^{( l - 1 ) / 2} \frac{4 {F}_{1}}{π i} sin ( i \frac{{N}_{s} {θ}_{pm}}{4} ) \times \\ \{ 1 + {\sum }_{z = 1 , 2 , 3}^{( n - 2 ) / 2 n ≻ 2} 2 cos [ i \frac{z {N}_{s} ( {θ}_{pm} + {θ}_{tp} )}{2} ] \} \\ {F}_{d c}^{{n}_{i}} = {( - 1 )}^{( k + 1 ) / 2} \frac{{2}^{( n + 4 ) / 2} {F}_{2}}{π k} sin ( k \frac{{N}_{s} {θ}_{tp}}{4} ) \times \\ {\prod }_{z = 1}^{n / 2} cos [ k \frac{z {N}_{s} ( {θ}_{pm} + {θ}_{tp} )}{4} ]\end{matrix}$$

where F₁ and F₂ are the amplitudes of permanent magnet magnetomotive force and field winding magnetomotive force respectively, and z is a positive integer;

Step 1.2: calculate the rotor permeance with different stator split teeth according to the size parameters of the rotor part, the rotor permeance Λₜⁿ(θ,t) is expressed as follows:

$${Λ}_{r}^{n} ( θ , t ) = {\sum }_{j = 0 , 1 , 2 …}^{∞} {P}_{r}^{{n}_{j}} cos [ j {N}_{r}^{n} ( θ - ω t - {θ}_{0} ) ]$$

where θ₀ and ω are the rotor initial position angle and rotor rotation angular velocity respectively, j is a non negative integer, Pᵣⁿ^{ⱼ} is the j^{th} harmonic component of rotor permeance, and N, is the number of salient poles of rotor;

Step 1.3: flux density excited by permanent magnet excitation Bₚₘⁿ(n,θ,t) and flux density excited by field winding excitation B_{dc}ⁿ(n,θ,t) can be expressed as follows:

$$\{ \begin{matrix}{B}_{pm}^{n} ( n , θ , t ) = {\sum }_{i = 1 , 3 , 5 …}^{∞} {\sum }_{j = 0 , 1 , 2 …}^{∞} {F}_{pm}^{{n}_{i}} {P}_{r}^{{n}_{j}} \times \\ sin ( i \frac{{N}_{s}}{2} θ ) cos [ j {N}_{r}^{n} ( θ - ω t - {θ}_{0} ) ] = \\ \frac{1}{2} {\sum }_{i = 1 , 3 , 5 …}^{∞} {\sum }_{j = 0 , 1 , 2 …}^{∞} {B}_{m 1}^{{n}_{ij}} sin [ ( i \frac{{N}_{s}}{2} \pm j {N}_{r}^{n} ) θ ∓ j {N}_{r}^{n} ( ω t + {θ}_{0} ) ] \\ {B}_{d c}^{n} ( n , θ , t ) = {\sum }_{k = 1 , 3 , 5 …}^{∞} {\sum }_{j = 0 , 1 , 2 …}^{∞} {F}_{d c}^{{n}_{k}} {P}_{r}^{{n}_{j}} \times \\ sin ( k \frac{{N}_{s}}{2} θ ) cos [ j {N}_{r}^{n} ( θ - ω t - {θ}_{0} ) ] = \\ \frac{1}{2} {\sum }_{k = 1 , 3 , 5 …}^{∞} {\sum }_{j = 0 , 1 , 2 …}^{∞} {B}_{m 2}^{{n}_{kj}} sin [ ( k \frac{{N}_{s}}{2} \pm {jN}_{r}^{n} ) θ ∓ {jN}_{r}^{n} ( ω t + {θ}_{0} ) ]\end{matrix}$$

where Bₘ₁ⁿ^{ᵢⱼ} is the m1 order amplitude of magnetic flux density excited by permanent magnet excitation, Bₘ₂ⁿ^{ᵢⱼ} is the m2 order amplitude of magnetic flux density excited by Field winding excitation, the magnetic flux density harmonic m1 is generated by the interaction between the permanent magnet magnetomotive force and the rotor salient pole, and the magnetic flux density harmonic m2 is generated by the interaction between the field winding magnetomotive force and the rotor salient pole; the harmonic orders m1 and m2 are expressed as follows:

$$\{ \begin{matrix}m 1 = \vert i \frac{{N}_{s}}{2} \pm j {N}_{r}^{n} \vert \\ m 2 = \vert k \frac{{N}_{s}}{2} \pm j {N}_{r}^{n} \vert\end{matrix}$$

Step 1.4: according to the obtained permanent magnet excitation flux density Bₚₘⁿ(n,θ,t) and field winding excitation flux density B_{dc}ⁿ(n,θ,t), the each coil flux linkage of permanent magnet excitation Ψ_{cpm}(n,t) and the each coil flux linkage of field winding excitation Ψ_{cdc}(n,t) can be expressed as follows:

$$\{ \begin{matrix}{ψ}_{cpm} ( n , t ) = {n}_{a c} {r}_{g} {l}_{ef} {\int }_{0}^{2 π / {N}_{s}} {B}_{pm}^{n} ( n , θ , t ) d θ = \\ {\sum }_{i = 1 , 3 , 5 …}^{∞} {\sum }_{j = 0 , 1 , 2 …}^{∞} \frac{{n}_{a c} {r}_{g} {l}_{e f} {B}_{m 1}^{{n}_{ij}}}{( i \frac{{N}_{s}}{2} \pm j {N}_{r}^{n} )} sin ( i \frac{π}{2} \pm j \frac{{N}_{r}^{n} π}{{N}_{s}} ) \times \\ sin [ i \frac{π}{2} \pm j {N}_{r}^{n} ( \frac{π}{{N}_{s}} - ω t - {θ}_{0} ) ] \\ {ψ}_{c d c} ( n , t ) = {n}_{a c} {r}_{g} {l}_{e f} {\int }_{0}^{2 π / {N}_{s}} {B}_{d c}^{n} ( n , θ , t ) d θ = \\ {\sum }_{k = 1 , 3 , 5 …}^{∞} {\sum }_{j = 0 , 1 , 2 …}^{∞} \frac{{n}_{a c} {r}_{g} {l}_{e f} {B}_{m 2}^{{n}_{kj}}}{( k \frac{{N}_{s}}{2} \pm j {N}_{r}^{n} )} sin ( k \frac{π}{2} \pm j \frac{{N}_{r}^{n} π}{{N}_{s}} ) \times \\ sin [ k \frac{π}{2} \pm j {N}_{r}^{n} ( \frac{π}{{N}_{s}} - ω t - {θ}_{0} ) ]\end{matrix}$$

where n_{ac} is the number of series turns of each coil, r_{g} is the air gap length, and l_{ef} is the effective axial length;

Step 1.5: calculate the back-EMF of each coil through the flux linkage value; the permanent magnet excitation back-EMF e_{cpm} and field winding excitation back-EMF e_{cdc} are expressed as follows:

$$\{ \begin{matrix}{e}_{cpm} ( t ) = - \frac{d {ψ}_{Apm} ( n , t )}{dt} = {\sum }_{i = 1 , 3 , 5 …}^{∞} {\sum }_{j = 0 , 1 , 2 …}^{∞} \frac{- {jN}_{r}^{n} ω {n}_{a c} {r}_{g} {l}_{ef} {B}_{m 1}^{{n}_{ij}}}{( i \frac{{N}_{s}}{2} \pm {jN}_{r}^{n} )} \times \\ cos ( j \frac{{N}_{r}^{n} π}{{N}_{s}} ) sin [ {jN}_{r}^{n} ( \frac{π}{{N}_{s}} - ω t - {θ}_{0} ) ] \\ {e}_{cdc} ( t ) = - \frac{d {ψ}_{Adc} ( n , t )}{dt} = {\sum }_{k = 1 , 3 , 5 …}^{∞} {\sum }_{j = 0 , 1 , 2 …}^{∞} \frac{- {jN}_{r}^{n} ω {n}_{a c} {r}_{g} {l}_{ef} {B}_{m 2}^{{n}_{kj}}}{( k \frac{{N}_{s}}{2} \pm {jN}_{r}^{n} )} \times \\ cos ( j \frac{{N}_{r}^{n} π}{{N}_{s}} ) sin [ {jN}_{r}^{n} ( \frac{π}{{N}_{s}} - ω t - {θ}_{0} ) ]\end{matrix}$$

where ψ_{Apm} is the permanent magnet flux, and ψ_{Adc} is the DC current flux.

Step 1.6: according to the back-EMF formula obtained by the previous step, only when j=1, the fundamental component of back-EMF is generated, so the working harmonics is generated by the 1^{st} permeance harmonics; the fundamental component of back-EMF E_{cpm} of permanent magnet excitation and the fundamental component of back-EMF E_{cdc} of field winding excitation are expressed as:

$$\{ \begin{matrix}{E}_{cpm} = {\sum }_{i = 1 , 3 , 5 …}^{∞} \frac{- {N}_{r}^{n} ω {n}_{a c} {r}_{g} {l}_{ef} {B}_{m 1}^{{n}_{i 1}}}{( i \frac{{N}_{s}}{2} \pm {N}_{r}^{n} )} cos ( \frac{{N}_{r}^{n} π}{{N}_{s}} ) \\ {N}_{cdc} = {\sum }_{k = 1 , 3 , 5 …}^{∞} \frac{- {N}_{r}^{n} ω {n}_{a c} {r}_{g} {l}_{ef} {B}_{m 2}^{{n}_{k 1}}}{( k \frac{{N}_{s}}{2} \pm {N}_{r}^{n} )} cos ( \frac{{N}_{r}^{n} π}{{N}_{s}} )\end{matrix}$$

where ω, n_{ac}, r_{g} and l_{ef} are constant values; in addition, for a fixed number of split teeth, Bₘ₁ⁿ^{ᵢ₁} and Bₘ₂ⁿ^{ₖ₁} are also constant values; by comparing the calculation results of back-EMF E_{cpm} excited by permanent magnet and back-EMF E_{cdc} excited by field winding, the optimal number of rotor salient poles with the best back-EMF E_{cpm} excited by permanent magnet and back-EMF E_{cdc} excited by field winding are obtained for each split tooth number.

Further, the specific process of step 2 is as follows:

Step 2.1: select the appropriate value ranges of θₚₘ and θₜₚ, which must meet the following requirements:

$$\{ \begin{matrix}( n - 1 ) {θ}_{pm} + n {θ}_{tp} \leq 360 / {N}_{s} - 4 \\ {θ}_{c} \geq 4 , {θ}_{pm} > 0 , {θ}_{tp} > 0\end{matrix}$$

where θ_{c} is the notch pole arc; in order to ensure the feasibility of the winding assembly process, θ_{c} satisfies a certain angle;
Step 2.2: substitute the specific n, θₚₘ and θₜₚ into the magnetomotive force calculation formula to calculate the corresponding Fₚₘⁿⁱ and F_{dc}^{nk};
Step 2.3: calculate the effective magnetomotive force ΣFₚₘ and ΣF_{dc} under the specific n, θₚₘ and θₜₚ according to the following formula:

$$\{ \begin{matrix}\sum {F}_{pm} = {\sum }_{{i = 1 , 3 , 5 …}_{j = 1}} {c}_{i} \frac{{N}_{r}^{n}}{m 1} \vert {F}_{pm}^{{n}_{i}} \vert \\ \sum {F}_{d c} = {\sum }_{{k = 1 , 3 , 5 …}_{j = 1}} {c}_{k} \frac{{N}_{r}^{n}}{m 2} \vert {F}_{d c}^{{n}_{k}} \vert\end{matrix}$$

where cᵢ represents the positive and negative contribution of the magnetic flux density of m1 order modulated by the magnetomotive force of i^{th} order by the permanent magnet excitation; when the magnetic flux density is a positive contribution, cᵢ=1; when the magnetic flux density is a negative contribution, cᵢ=−1; cₖ represents the positive and negative contribution of the magnetic flux density of m2 order modulated by the magnetic motiveforce of k^{th} order by the field winding excitation; when the magnetic flux density is positive contribution, cₖ=1; when the magnetic flux density is negative contribution, cₖ=−1;

Step 2.4: calculate the corresponding ΣFₚₘ and ΣF_{dc} with different n, θₚₘ and θₜₚ according to step 2.3; draw the curves of ΣFₚₘ and ΣF_{dc} with the change of θₚₘ and θₜₚ under the same n; from the variation of the curves, select the optimal selection area and optimal structural parameters of θₚₘ and θₜₚ.

Further, step 1 also includes: the DC current part is field winding excitation, the motor generates field winding magnetic field, which flows in and out of the air gap through the splitting teeth (5) to form an effective field winding flux path; the number of splitting teeth (5) increases with the increase of the number of splitting teeth (5), and the magnetic field increases first and then decreases; when permanent magnet (6) generates permanent magnet magnetic field, it enters and exits the air gap through the permanent magnet to form an effective permanent magnet flux path; as the number of split teeth increases, the number of permanent magnets (6) increases and the permanent magnet magnetic field further strengthens, while the permanent magnet flux path has nothing to do with the number of split teeth.

Further, in step 2, on the basis of determining the optimal number of split teeth n, the mathematical models of permanent magnet excitation effective magnetomotive force ΣFₚₘ and effective field winding excitation magnetomotive force ΣF_{dc} are established; the influence of permanent magnet and DC current on motor performance is analyzed directly from the perspective of magnetomotive force; by calculating the variation of effective permanent magnet excitation magnetomotive force ΣFₚₘ and effective field winding excitation magnetomotive force ΣF_{dc} under the change of the pole arc of permanent magnet θₚₘ and split tooth arc θₜₚ, the optimal selection areas of the two pole arcs are obtained, so as to obtain the optimized structural parameters of the motor; it also provides a simple and convenient parameter region determination method for the selection of the optimal initial size range of the motor, so as to improve the utilization efficiency of the hybrid excitation magnetic field, so as to effectively enhance the torque density and flux regulation ability of the single winding hybrid excitation magnetic field modulation motor; in addition, the design method based on hybrid dual field magnetomotive force further improves the efficiency of motor design and reduces the research and development cycle and cost of motor.

According to the requirements of different applications, the motor structure can be an internal rotor structure, or an external rotor structure.

After adopting the above design scheme, the present disclosure can have the following beneficial effects:

A single winding hybrid excitation magnetic field modulation motor of the present disclosure only uses one set of windings, and provides a rotating magnetic field and an excitation magnetic field at the same time, so that the space competition and the difficulty of the winding processing technology caused by the increase of the field winding of the traditional double excitation motor are effectively alleviated and enhancing the motor slot full rate. On this basis, the design of any number of split teeth and the number of salient rotor poles provides a broad degree of design freedom for realizing the dual excitation of field winding and PM to improve torque density and flux regulation ability.

The present disclosure starts from the magnetomotive force of each excitation source, analyzes the influence of the number of split teeth, the number of stator teeth and the number of rotor salient poles on performance, and obtains the optimal selection method of the number of rotor salient poles under different numbers of split teeth of this type of dual excitation motor; further, according to the design characteristics of the split tooth arc and permanent magnet arc of this type of hybrid excitation motor, and using the magnetomotive force as the design medium, determine the optimal design range of the split tooth arc and the permanent magnet arc, and optimize the initial stage for the motor. The selection of the size range provides a simple and convenient method for determining the parameter area, which can improve the utilization efficiency of the dual excitation magnetic field, thereby effectively enhancing the torque density and magnetic adjustment capability of the single winding dual excitation magnetic field modulation motor. In addition, the design method based on the synergistic dual magnetic field magnetomotive force also further improves the efficiency of motor design work and reduces the research and development cycle and cost of motor.

A single winding hybrid excitation magnetic field modulation motor proposed by the present disclosure, from the perspective of the overall structural design, all excitation sources are placed on the stator side, eliminating slip rings and armature winding, effectively improving the reliability of motor operation, and advantageously unifying management of excitation source temperature; the rotor side is only a simple salient pole structure, which improves the reliability of high-speed operation. The stator of the present disclosure adopts the alternate arrangement of split teeth and permanent magnets, and designs the field winding excitation flux path and the permanent magnet excitation flux path in parallel, so as to avoid the risk of irreversible demagnetization of the permanent magnets.

### BRIEF DESCRIPTION OF THE DRAWINGS

FIG. 1 is a schematic structural diagram of a single winding hybrid excitation magnetic field modulation motor according to Example 1 of the present disclosure.

FIG. 2 is a schematic structural diagram of a single-winding hybrid excitation magnetic field modulation motor according to Example 2 of the present disclosure.

FIG. 3 is a schematic structural diagram of a single-winding hybrid excitation magnetic field modulation motor according to Example 3 of the present disclosure.

FIG. 4 is a schematic diagram of the connection between the winding and the driving circuit of the example of the present disclosure.

FIG. 5 is a schematic diagram of the effective permanent magnet flux path only with permanent magnet excitation according to the example of the present disclosure.

FIG. 6 is a schematic diagram of effective field winding flux path only with field winding excitation according to the example of the present disclosure and the permanent magnet is set to air.

FIG. 7A is the magnetomotive force model of a single winding hybrid excitation magnetic field modulation motor with only permanent magnet excitation.

FIG. 7B is the magnetomotive force model of a single winding hybrid excitation magnetic field modulation motor only with field winding excitation.

FIG. 8 is the amplitude of the fundamental wave of the back-EMF varies with the number of salient poles of the rotor, when the permanent magnet excitation and the field winding excitation of a single winding hybrid excitation magnetic field modulation motor according to the example of the present disclosure acting separately.

FIG. 9A shows variation of the effective magnetomotive force ΣFₚₘ with the permanent magnet arc θₚₘ and the split tooth arc θₜₚ only with permanent magnet excitation of the single winding hybrid excitation magnetic field modulation motor of the Example. 2 of the present disclosure.

FIG. 9B shows variation of the back-EMF fundamental amplitude with the permanent magnet arc θₚₘ and the split tooth arc θₜₚ only with permanent magnet excitation of the single winding hybrid excitation magnetic field modulation motor of the Example. 2 of the present disclosure.

FIG. 10A shows variation of the effective magnetomotive force ΣF_{dc} with the permanent magnet arc θₚₘ and the split tooth arc θₜₚ only with field winding excitation of the single winding hybrid excitation magnetic field modulation motor of the Example. 2 of the present disclosure.

FIG. 10B shows variation of the back-EMF fundamental amplitude with the permanent magnet arc θₚₘ and the split tooth arc θₜₚ only with field winding excitation of the single winding hybrid excitation magnetic field modulation motor of Example. 2 of the present disclosure.

FIG. 11 is the cogging torque waveform of a single winding hybrid excitation magnetic field modulation motor according to the example of the present disclosure.

FIG. 12 is the output torque of a single winding hybrid excitation magnetic field modulation motor according to the example of the present disclosure when the AC and DC copper losses are 37 W and 13 W respectively.

FIG. 13 is the contribution of each working harmonics to the back-EMF fundamental amplitude of a single winding hybrid excitation magnetic field modulation motor according to the example of the present disclosure.

FIG. 14 is the comparison of the back-EMF fundamental amplitude by analytical method and finite element method with only permanent magnet excitation of the single winding hybrid excitation magnetic field modulation motor according to the example.

FIG. 15 is the comparison of the back-EMF fundamental amplitude by analytical method and finite element method with only field winding excitation of the single winding hybrid excitation magnetic field modulation motor according to the example.

FIG. 16 is the variation of the back-EMF fundamental amplitude with the DC current when only DC current is passed through the winding of the single winding hybrid excitation magnetic field modulation motor according to the example of the present disclosure

In the drawings: 1. rotor, 2. stator yoke, 3. stator teeth, 4. winding coil, 5. split teeth, 6. permanent magnet.

### DETAILED DESCRIPTION OF THE EMBODIMENTS

In order to make the objectives, technical solutions and effects of the present disclosure clearer, the following describes the structural features and beneficial effects of the motor of the present disclosure in detail with reference to the accompanying drawings and specific examples.

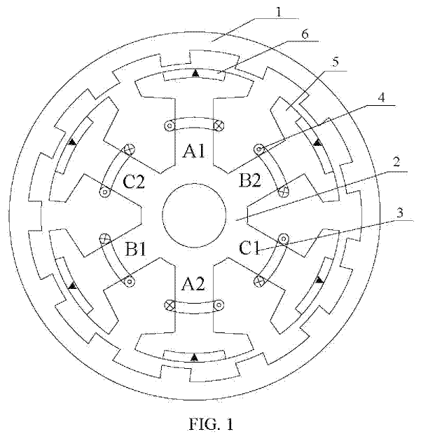

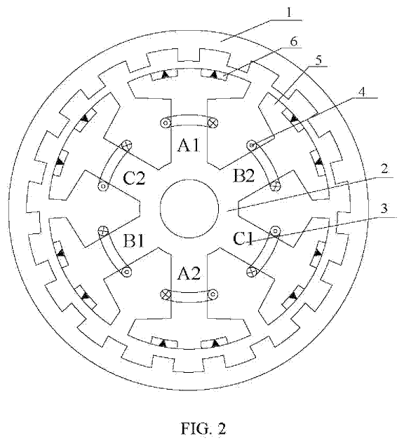

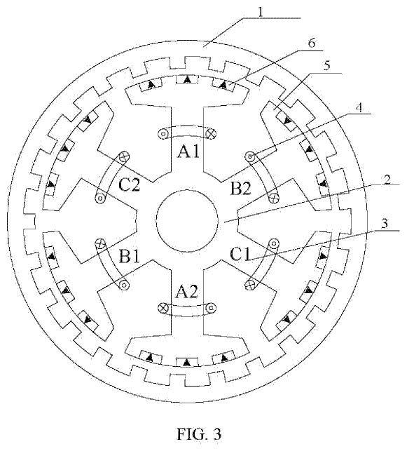

The present disclosure provides a single winding hybrid excitation magnetic field modulation motor and a synergy excitation design method thereof. The specific implementation objects are shown in FIGS. 1-3. As shown in the figures, the example objects all include a stator and a rotor (1), and the stator includes a stator core, permanent magnets (6) and windings, wherein the stator core consists of six stator teeth (3) and one stator yoke (2); specifically: each stator tooth (3) of Example 1 is split along the ends into two split teeth (5), the permanent magnet (6) is embedded at the end of the stator teeth, each permanent magnet (6) is sandwiched by two split teeth (5), and all permanent magnets (6) on the same stator tooth (3) have the same polarity, and the permanent magnets (6) on adjacent stator teeth (3) have opposite polarities. The total number Nₚₘ of permanent magnets (6) in the motor is 6, the total number of split teeth (5) is 12, and the number of rotor salient poles is 13; each stator tooth (3) of Example 2 is split along the end 3 split teeth (5), the permanent magnet (6) is embedded in the end of the stator teeth, each permanent magnet (6) is sandwiched by two split teeth (5), and all the polarities of the permanent magnets (6) are the same, the polarities of the permanent magnets (6) on the adjacent stator teeth (3) are opposite, the total number Nₚₘ of the permanent magnets (6) in the motor is 12, and the total number of split teeth (5) is 18, and the number of rotor salient poles is 19; each stator tooth (3) of Example 3 is split into 4 split teeth (5) along the end, and the permanent magnet (6) is embedded in the end of the stator tooth, each the permanent magnet (6) is sandwiched by two split teeth (5), and all the permanent magnets (6) on the same stator tooth (3) have the same polarity, and the permanent magnets (6) on the adjacent stator teeth (3) have the opposite polarity, the total number Nₚₘ of permanent magnets (6) in the motor is 18, the total number of split teeth (5) is 24, and the number of rotor salient poles is 25.

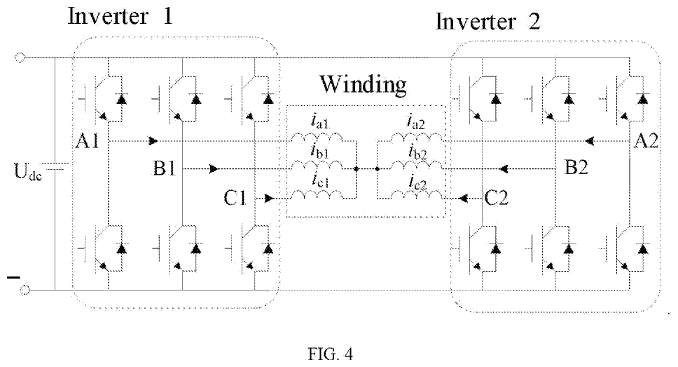

The windings in example 1-3 are all composed of six coils (4), and each coil (4) is centrally wound on different stator teeth (3), which are respectively: A1, C2, B1, A2, C1, B2. Both DC current and AC current are introduced into each coil (4). The DC current generates a field winding magnetic field, while the AC current generates a rotating magnetic field. As shown in FIG. 4, A1, B1 and C1 adopt star connection to form a set of three-phase windings; A2, B2 and C2 also adopt star connection to form another set of three-phase windings. The two sets of three-phase windings are controlled by two three-phase inverter circuits respectively. The two sets of three-phase windings are connected into star connection and the neutral points are connected. The field winding excitation field is controlled by adjusting the DC current flowing the neutral point. The permanent magnets on the stator teeth wound by each set of three-phase windings have the same polarity, but the polarities of the permanent magnets on the stator teeth wound by different three-phase windings are opposite. The magnetic field generated by the field winding and PM work together to form hybrid excitation. The DC current of the two sets of windings is the same in size but opposite in direction. The direction of the current is determined by the Right Hand Rule, so that the magnetic field direction formed by the two sets of windings can be in the same or opposite direction with the magnetization direction of the permanent magnet on the stator teeth. Thus, the mutual enhancement (flux enhancing effect) or mutual weakening (flux weakening effect) of the field winding excitation magnetic field formed by the DC current and the permanent magnet magnetic field are realized.

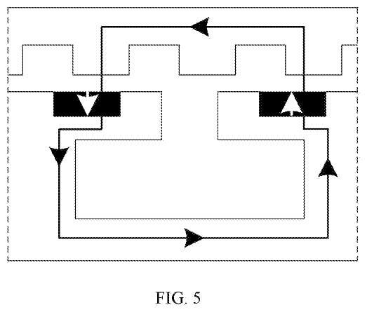

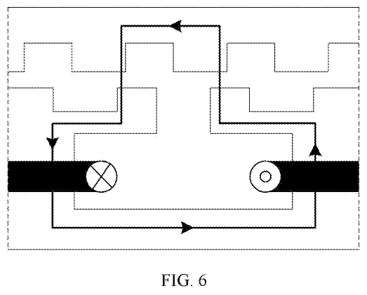

Although the number of splitting teeth, the number of permanent magnets and the number of salient poles of the rotor are different in different examples, the flux paths of effective permanent magnet and the field winding are the same. FIG. 5 shows the permanent magnet flux path under only permanent magnet excitation, and the flux path enters and exits the air gap through the permanent magnet to form a closed loop. FIG. 6 shows the path of field winding flux with only field winding excitation. The flux path enters and exits the air gap through the split tooth to form a closed loop. The permanent magnet flux path and the field winding flux path are parallel to each other.

The present disclosure relates to a single winding hybrid excitation magnetic field modulation motor and a synergy excitation design method thereof, including the following steps:

Step 1, firstly, Based on the theory of magnetic field modulation, back-EMF E_{cpm} excited by permanent magnet and back-EMF E_{cdc} excited by field winding are derived when the number of split teeth n and the number of rotor salient poles are both changed; by comparing the calculation results of back-EMF E_{cpm} excited by permanent magnet and back-EMF E_{cdc} excited by field winding, the optimal number of rotor salient poles with the best back-EMF E_{cpm} excited by permanent magnet and back-EMF E_{cdc} excited by field winding are obtained for each split tooth number;

Step 2, then on the basis of determining the optimal number of split teeth n and the number of rotor salient poles, the effects of the pole arc of permanent magnet θₚₘ and split tooth arc θₜₚ on the permanent magnet excitation effective magnetomotive force ΣFₚₘ and effective field winding excitation magnetomotive force ΣF_{dc} are deduced; thus, the optimal selection region of the two pole arc parameters of the motor is obtained under the determination of the number of split teeth n and the number of rotor salient poles.

For the selection of the number of salient poles of the rotor in concrete Examples 1-3, include the following steps:

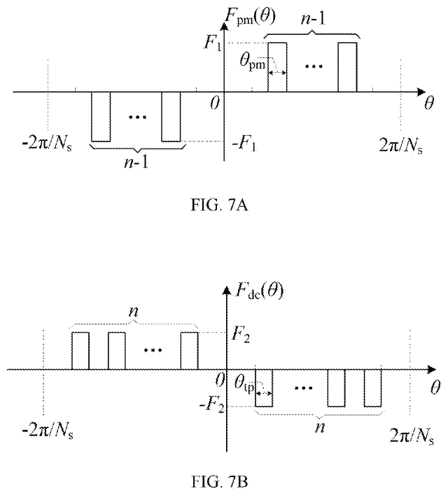

Step 1: as shown in FIGS. 7A-7B, FIG. 7A is the permanent magnet magnetomotive force model, and FIG. 7B is the field winding excitation magnetomotive force model, wherein Example 1, Example 2 and Example 3 correspond to n is 2, 3, 4. According to the design parameters of the stator part, the permanent magnet magnetomotive force and the field winding magnetomotive force when the stator split teeth n are calculated;

Step 2: according to some parameters of the rotor, calculate the rotor permeance of the three example respectively;

Step 3: multiply the magnetomotive force and the permeance to calculate the flux density of permanent magnet and field winding excitations;

Step 4: according to the obtained the flux density of permanent magnet and field winding excitations, calculate the permanent magnet excitation flux linkage and field winding excitation flux linkage in each set of windings;

Step 5: through the flux linkage value, obtain permanent magnet excitation back-EMF and field winding excitation back-EMF of each set of windings;

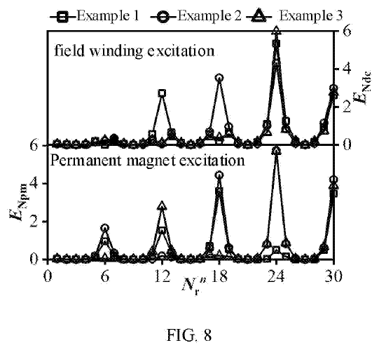

Step 6: according to the back-EMF formula obtained in the previous step, fundamental component of back-EMF by permanent magnet excitation and fundamental component of back-EMF by field winding excitation are obtained. FIG. 8 plots the corresponding permanent magnet excitation back-EMF and Field winding excitation back-EMF when three examples of rotor salient pole numbers vary from 1 to 30. Through the data comparison in the figure, it can be concluded that the number of rotor salient poles selected in the three examples is the best;

In addition to the design of the number of salient poles of the rotor, the optimal selection of the permanent magnet pole θₚₘ and split tooth arc θₜₚ is obtained by calculating the effective magnetomotive force area of permanent magnet excitation ΣFₚₘ and the effective magnetomotive force of field winding excitation ΣF_{dc}, the specific steps are as follows:

Step 1: select the appropriate value range of θₚₘ and θₜₚ respectively, where the value range of θₚₘ is: 7 deg˜12 deg, and the value range of θₜₚ is: 5 deg˜9 deg;

Step 2: substitute the specific n, θₚₘ and θₜₚ into the magnetomotive force calculation formula to calculate the corresponding Fₚₘⁿⁱ and F_{dc}^{nk}.

Step 3: calculate the effective magnetomotive force ΣFₚₘ and ΣF_{dc} under the specific n, θₚₘ and θₜₚ according to the following formulas.

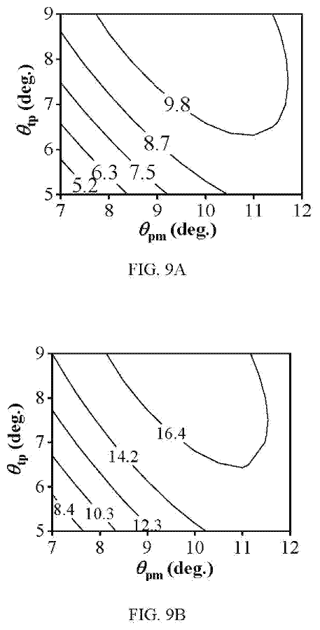

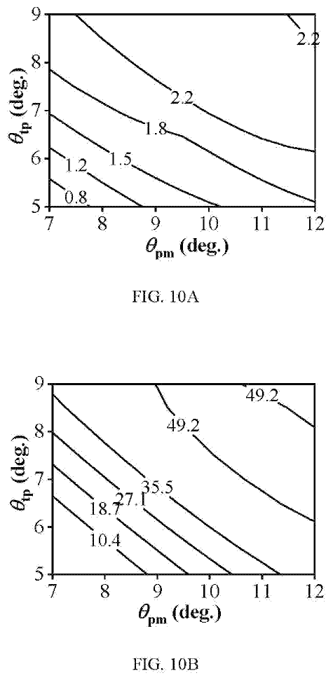

Step 4: calculate the corresponding ΣFₚₘ and ΣF_{dc} in Example 2 according to Step 3. FIGS. 9A-9B show the effect of variation in θₚₘ and θₜₚ on performance by permanent magnet excitation. FIG. 9A shows the influence of the variation of θₚₘ and θₜₚ on ΣFₚₘ according to the above analysis, and FIG. 9B shows the influence of the variation of θₚₘ and θₜₚ obtained by finite element method on the back-EMF; FIGS. 10A-10B show the influence of θₚₘ and θₜₚ variation on performance with field winding excitation. FIG. 10A shows the influence of the variation of θₚₘ and θₜₚ on ΣF_{dc}, which is obtained by analytical method. FIG. 10B shows the influence of the variation of θₚₘ and θₜₚ on the back-EMF, which is obtained by finite element method. From the figure, the results of the finite element method and the analytical method can be compared to verify the correctness of the above steps. In addition, the optimal selection region of θₚₘ and θₜₚ can also be obtained by this method.

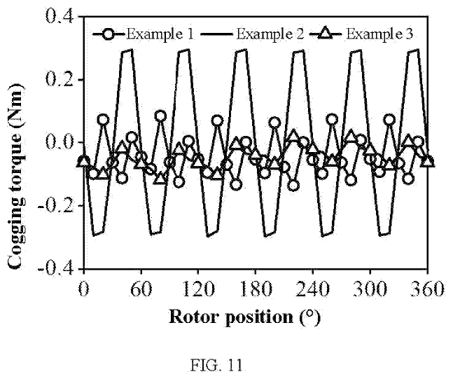

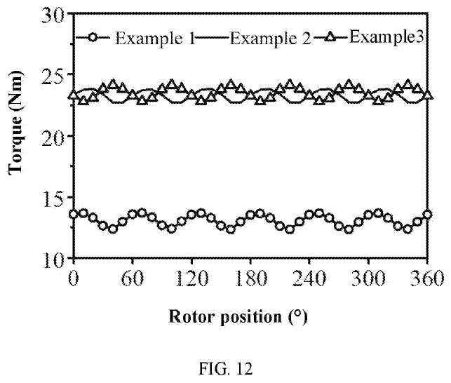

FIG. 11 shows the cogging torque of Examples 1-3. The cogging torque of the three examples is very small, and the maximum cogging torque of Example 2 is 0.3 Nm; FIG. 12 shows the torque waveforms of the three examples. When the AC current copper loss is 37 W and the DC current copper loss is 13 W, the torques of Examples 1-3 are 13.1 Nm, 23.2 Nm and 23.4 Nm, respectively, and the corresponding torque ripples are: 10.4%, 4.8% and 5.8%. The torque of Example 2 is basically the same as that of Example 3, while the torque ripple of Example 2 is smaller. Compared with Example 1, the torque of Examples 2 and 3 is increased by 77% and 79%, respectively.

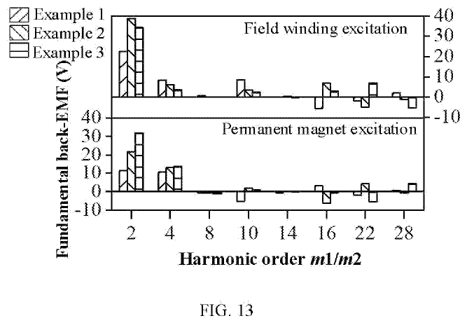

FIG. 13 shows the contribution of each working harmonics of Examples 1-3 to the fundamental component of back-EMF. The working harmonic order of permanent magnet excitation and field winding excitation are the same, respectively; they are 2^{nd}, 4^{th}, 8^{th}, 10^{th}, 14^{th}, 16^{th}, 22^{nd} and 28^{th}, among which, the amplitudes of the 8^{th} and 14^{th} are small and can be ignored; with permanent magnet excitation, the negative contribution working orders of Example 1 are 10^{th} and 22^{nd}; The negative contribution working harmonic orders of Example 2 are: 16^{th} and 28^{th}, the negative contribution working harmonics orders of Example 3 are 22^{nd}; with only field winding excitation, the negative contribution working harmonics orders of Example 1 are 16^{th} and 22^{nd}, the negative contribution working harmonics orders of Example 2 are 22^{nd} and 28^{th}, the negative contribution working harmonics orders of Example 3 are 28^{th}.

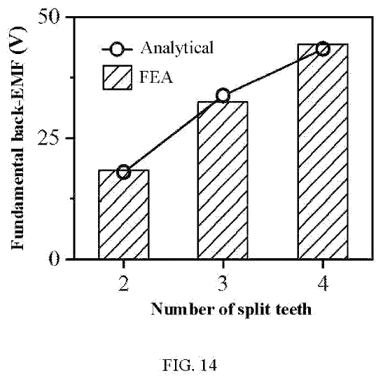

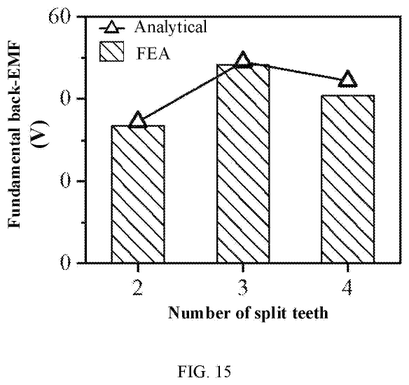

FIG. 14 shows the back-EMF fundamental amplitude generated with only permanent magnet excitation of Example 1-3. The numbers of split teeth 2, 3, and 4 in the figure correspond to Examples 1, 2, and 3, respectively. It can be seen that the results by analytical method and finite element method are basically consistent, and the amplitude of the back-EMF increases with the increase of the number of split teeth. In the figure, the back-EMF fundamental amplitude in Example 3 is the highest; in addition, FIG. 15 shows the amplitude of the fundamental back-EMF generated when the Field winding excitation acts alone. It can be seen from the figure that the amplitude of the back-EMF first increases and then decreases with the increase of the number of split teeth, and the amplitude of the back-EMF of Example 2 is the largest.

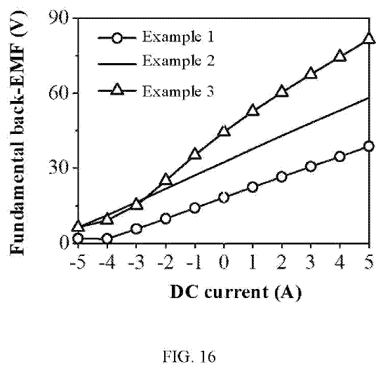

FIG. 16 shows the variation of the amplitude of the fundamental back-EMF by the Field winding excitation. It can be seen that the field winding excitation in Examples 1-3 has the ability to regulate the motor magnetic field. Among them, the variation range of Example 3 is the largest, while Example 1 has the smallest range of variation.

To sum up, the single winding hybrid excitation magnetic field modulation motor designed by the present disclosure has only one set of windings, and provides both the armature magnetic field and the field winding excitation magnetic field, so that the space competition and the difficulty of the winding processing technology caused by the increase of the excitation winding of the dual-excitation motor are alleviated. The alternate arrangement of split teeth and permanent magnets on the stator side effectively designs the permanent magnet flux path and the field winding flux path in parallel to avoid the risk of irreversible demagnetization of the permanent magnets; starting with the magnetomotive force and permeability model of each excitation source, different topologies of the change of the number of split teeth are studied, and the expressions of the effect of the number of split teeth, the number of stator teeth and the number of rotor salient poles on performance are deduced, and the optimal selection method of the number of rotor salient poles under different number of split teeth of this type of the hybrid excitation motor is obtained. According to the design characteristics of the split tooth pole arc and permanent magnet pole arc of this type of dual excitation motor, and using the magnetomotive force as the design medium, determine the optimal design range of the split tooth pole arc and the permanent magnet pole arc, and optimize the initial size range for the motor. The selection provides a simple and convenient parameter area determination method to improve the utilization efficiency of the hybrid excitation magnetic field, thereby improving the output torque and magnetic adjustment capability of the motor. In addition, the design method based on hybrid excitation magnetic field magnetomotive force also further improves the efficiency of motor design work and reduces the motor research and development cycle and cost. From the perspective of the overall structure design of the motor, all excitation sources are placed on the stator side, eliminating slip rings and armature winding, which effectively improves the reliability of motor operation and facilitates unified management of the excitation source temperature; the rotor side is only a simple salient pole structure, which improves the reliability of high-speed operation.

Although examples of the present disclosure have been illustrated and described, it will be understood by those of ordinary skill in the art is that numerous variation, modifications, substitutions and alterations can be made to these examples without departing from the principles and spirit of the present disclosure, the scope of which is defined by the appended claims and their equivalents.

1. A single winding hybrid excitation magnetic field modulation motor, comprising a stator and a rotor, wherein
the stator comprises a stator core, a permanent magnet and a winding, wherein
the stator core is composed of Nₛ stator teeth and a stator yoke;
each stator tooth is split into any equal number of n split teeth facing an air gap side and n>1, the permanent magnet is embedded in a groove between the split teeth on the same stator tooth, each permanent magnet is clamped by two split teeth on the same stator tooth, a number of the permanent magnets on each stator tooth is n−1, and a polarity of permanent magnets on the same stator tooth is the same;
the polarity of permanent magnets on two adjacent stator teeth is opposite, a total number Nₚₘ of the permanent magnets in the motor is (n−1)Nₛ, and a total number of the split teeth is nNₛ;
all stator teeth are wound with a single non overlapping concentrated winding;
each set of winding is connected with DC current and AC current at the same time, wherein a field winding and the permanent magnet are excited together to form hybrid excitation;
an amplitude of the DC current in all windings is equal, and a flow direction of the DC current is determined according to a magnetic field in an opposite direction of the DC current in adjacent windings, to generate an effective field winding excitation magnetic field and form effective hybrid excitation with the permanent magnet;
the rotor is composed of a rotor yoke and salient poles, and a number of the salient poles is nNₛ+m; wherein m is any natural number.

2. The single winding hybrid excitation magnetic field modulation motor according to claim 1, wherein
the winding is connected into two groups of three-phase windings, the two groups of three-phase windings are respectively controlled by two three-phase inverter circuits;
the field winding and the permanent magnet forms a hybrid excitation magnetic field to provide excitation for the motor, while and a three-phase AC current in the winding generates a rotating magnetic field and interacts with the hybrid excitation magnetic field to produce continuous torque;
the winding wound on the stator teeth with a first permanent magnet with the same polarity forms a group of three-phase windings, and the winding wound on the stator teeth with a second permanent magnet with the same polarity forms a second group of three-phase windings;
an excitation magnetic field generated by the DC current and a permanent magnet magnetic field generated by the permanent magnet acting together to produce hybrid excitation effect;
the DC current of the two groups of three-phase windings is the same, and the flow direction of the DC current is determined according to the magnetic field in the opposite direction of the DC current in the adjacent windings;
an excitation magnetic field formed by the two groups of three-phase windings is flux enhancing effect when the excitation magnetic field is the same as a magnetic field direction of the permanent magnet on each stator tooth, and is flux weakening effect when the excitation magnetic field is opposite to the magnetic field direction of the permanent magnet on each stator tooth.

3. A synergy excitation design method of the single winding hybrid excitation magnetic field modulation motor according to claim 1, wherein
when m is an odd number, the two groups of three-phase windings are connected in a star connection and neutral points are connected, and a current on the neutral point is controlled to adjust the DC current to control the field winding excitation magnetic field;
when m is an even number, the two groups of three-phase windings are connected in the star connection but the neutral points are connected or the two groups of three-phase windings are connected in a delta connection; the DC current is controlled in each set of windings to control the field winding excitation magnetic field.

4. The single winding hybrid excitation magnetic field modulation motor according to claim 1, wherein a structure of the motor is an inner rotor structure or an outer rotor structure.

5. A synergy excitation design method of the single winding hybrid excitation magnetic field modulation motor according to claim 1, comprising the following steps:
step 1, based on the theory of magnetic field modulation, deriving a back-electromotive force (EMF) E_{cpm} excited by permanent magnet and a back-EMF E_{cdc} excited by the field winding when a number of the split teeth n and the number of the salient poles are both changed; comparing calculation results of the back-EMF E_{cpm} excited by the permanent magnet and the back-EMF E_{cdc} excited by the field winding, to obtain an optimal number of the salient poles with a best back-EMF E_{cpm} excited by the permanent magnet and the back-EMF E_{cdc} excited by the field winding for each split tooth number; and
step 2, then on the basis of determining an optimal number of the split teeth n and the number of the salient poles, deducing effects of a pole arc θₚₘ of the permanent magnet and a split tooth arc θₜₚ on a permanent magnet excitation effective magnetomotive force ΣFₚₘ and an effective field winding excitation magnetomotive force ΣF_{dc}, to obtain an optimal selection region of two pole arc parameters of the motor after determining the number of the split teeth n and the number of the salient poles.

6. The synergy excitation design method of the single winding hybrid excitation magnetic field modulation motor according to claim 5, wherein the specific process of step 1 is:
step 1.1: according to size parameters of the stator, calculating a permanent magnetomotive force and a field winding magnetomotive force of different stator split teeth n, wherein the permanent magnet magnetomotive force Fₚₘ(n,θ) and the field winding magnetomotive force F_{dc}(n,θ) expressed as follows:
$$\{ \begin{matrix}{F}_{pm} ( n , θ ) = {\sum }_{i = 1 , 3 , 5 …}^{∞} {F}_{pm}^{{n}_{i}} sin ( i \frac{{N}_{s}}{2} θ ) \\ {F}_{d c} ( n , θ ) = {\sum }_{k = 1 , 3 , 5 …}^{∞} {F}_{d c}^{{n}_{k}} sin ( k \frac{{N}_{S}}{2} θ )\end{matrix}$$
wherein Nₛ is a number of the stator teeth, i and k are positive integers, θ is a rotor position angle, Fₚₘⁿ^{ᵢ} is an i^{th} order amplitude component of the permanent magnet magnetomotive force and F_{dc}ⁿ^{ₖ} is a k^{th} order amplitude component of the field winding magnetomotive force; according to a parity of the number of the split teeth n, Fₚₘⁿ^{ᵢ} and F_{dc}ⁿ^{ₖ} have different expressions; when n is an odd number, Fₚₘⁿ^{ᵢ} and F_{dc}ⁿ^{ₖ} are expressed as:
$$\{ \begin{matrix}{F}_{pm}^{{n}_{i}} = {( - 1 )}^{( i - 1 ) / 2} \frac{{2}^{( n + 3 ) / 2} {F}_{1}}{π i} sin ( i \frac{{N}_{s} {θ}_{pm}}{4} ) \times \\ {\prod }_{z = 1 , 2 , 3 …}^{( n - 1 ) / 2} cos [ i \frac{z {N}_{s} ( {θ}_{pm} + {θ}_{tp} )}{4} ] \\ {F}_{d c}^{{n}_{k}} = {( - 1 )}^{( k + 1 ) / 2} \frac{4 {F}_{2}}{π k} sin ( k \frac{{N}_{s} {θ}_{tp}}{4} ) \times \\ \{ 1 + {\sum }_{z = 1 , 2 , 3 …}^{( n - 1 ) / 2} 2 cos [ k \frac{z {N}_{s} ( {θ}_{pm} + {θ}_{tp} )}{2} ] \}\end{matrix}$$
wherein the pole arc of the permanent magnet is denoted as θₚₘ, and the split tooth arc is denoted as θₜₚ, when n is an even number, Fₚₘⁿ^{ᵢ} and F_{dc}ⁿ^{ₖ} are expressed as:
$$\{ \begin{matrix}{F}_{pm}^{{n}_{i}} = {( - 1 )}^{( i - 1 ) / 2} \frac{4 {F}_{1}}{π i} sin ( i \frac{{N}_{s} {θ}_{pm}}{4} ) \times \\ \{ 1 + {\sum }_{z = 1 , 2 , 3}^{( n - 2 ) / 2 , n ≻ 2} 2 cos [ i \frac{z {N}_{s} ( {θ}_{pm} + {θ}_{tp} )}{2} ] \} \\ {F}_{d c}^{{n}_{i}} = {( - 1 )}^{( k + 1 ) / 2} \frac{{2}^{( n + 4 ) / 2} {F}_{2}}{π k} sin ( k \frac{{N}_{s} {θ}_{tp}}{4} ) \times \\ {\prod }_{z = 1}^{n / 2} cos [ k \frac{z {N}_{s} ( {θ}_{pm} + {θ}_{tp} )}{4} ]\end{matrix}$$
wherein F₁ and F₂ are amplitudes of the permanent magnet magnetomotive force and the field winding magnetomotive force respectively, and z is a positive integer,
step 1.2: calculating rotor permeance with different stator split teeth according to size parameters of the rotor, the rotor permeance Λₜⁿ(θ,t) is expressed as follows:
$${Λ}_{r}^{n} ( θ , t ) = {\sum }_{j = 0 , 1 , 2 …}^{∞} {P}_{r}^{{n}_{j}} cos [ j {N}_{r}^{n} ( θ - ω t - {θ}_{0} ) ]$$
wherein θ₀ and ω are a rotor initial position angle and a rotor rotation angular velocity respectively, j is a non negative integer, Pₜⁿ^{ᵢ} is a j^{th} harmonic component of rotor permeance, and Nₜⁿ is the number of the salient poles of the rotor;
step 1.3: expressing a flux density excited by permanent magnet excitation Bₚₘⁿ(n,θ,t) and a flux density excited by field winding excitation B_{dc}ⁿ(n,θ,t) as follows:
$$\{ \begin{matrix}{B}_{pm}^{n} ( n , θ , t ) = {\sum }_{i = 1 , 3 , 5 …}^{∞} {\sum }_{j = 0 , 1 , 2 …}^{∞} {F}_{pm}^{{n}_{i}} {P}_{r}^{{n}_{j}} \times \\ sin ( i \frac{{N}_{s}}{2} θ ) cos [ j {N}_{r}^{n} ( θ - ω t - {θ}_{0} ) ] = \\ \frac{1}{2} {\sum }_{i = 1 , 3 , 5 …}^{∞} {\sum }_{j = 0 , 1 , 2 …}^{∞} {B}_{m 1}^{{n}_{ij}} sin [ ( i \frac{{N}_{s}}{2} \pm {jN}_{r}^{n} ) θ ∓ {jN}_{r}^{n} ( ω t + {θ}_{0} ) ] \\ {B}_{d c}^{n} ( n , θ , t ) = {\sum }_{k = 1 , 3 , 5 …}^{∞} {\sum }_{j = 0 , 1 , 2 …}^{∞} {F}_{d c}^{{n}_{k}} {P}_{r}^{{n}_{j}} \times \\ sin ( k \frac{{N}_{s}}{2} θ ) cos [ j {N}_{r}^{n} ( θ - ω t - {θ}_{0} ) ] = \\ \frac{1}{2} {\sum }_{k = 1 , 3 , 5 …}^{∞} {\sum }_{j = 0 , 1 , 2 …}^{∞} {B}_{m 2}^{{n}_{kj}} sin [ ( k \frac{{N}_{s}}{2} \pm {jN}_{r}^{n} ) θ ∓ {jN}_{r}^{n} ( ω t + {θ}_{0} ) ]\end{matrix}$$
wherein Bₘ₁ⁿ^{ᵢ} is a m1 order amplitude of the magnetic flux density excited by the permanent magnet excitation, Bₘ₂ⁿ^{ₖⱼ} is a m2 order amplitude of the magnetic flux density excited by the field winding excitation, a first magnetic flux density harmonic m1 is generated by an interaction between the permanent magnet magnetomotive force and the salient pole of the rotor, and a second magnetic flux density harmonic m2 is generated by an interaction between the field winding magnetomotive force and the salient pole of the rotor; the harmonic orders m1 and m2 are expressed as follows:
$$\{ \begin{matrix}m 1 = \vert i \frac{{N}_{s}}{2} \pm j {N}_{r}^{n} \vert \\ m 2 = \vert k \frac{{N}_{s}}{2} \pm j {N}_{r}^{n} \vert\end{matrix}$$
step 1.4: according to the flux density Bₚₘⁿ(n,θ,t) obtained by the permanent magnet excitation and the flux density B_{dc}ⁿ(n,θ,t) obtained by the field winding excitation, expressing each coil flux linkage of the permanent magnet excitation Ψ_{cpm}(n,t) and each coil flux linkage of the field winding excitation Ψ_{cdc}(n,t) as follows:
$$\{ \begin{matrix}{ψ}_{c p m} ( n , t ) = {n}_{a c} {r}_{g} {l}_{ef} {\int }_{0}^{2 π / {N}_{s}} {B}_{pm}^{n} ( n , θ , t ) d θ = \\ {\sum }_{i = 1 , 3 , 5 …}^{∞} {\sum }_{j = 0 , 1 , 2 …}^{∞} \frac{{n}_{a c} {r}_{g} {l}_{ef} {B}_{m 1}^{{n}_{ij}}}{( i \frac{{N}_{s}}{2} \pm {jN}_{r}^{n} )} sin ( i \frac{π}{2} \pm j \frac{{N}_{r}^{n} π}{{N}_{s}} ) \times \\ sin [ i \frac{π}{2} \pm {jN}_{r}^{n} ( \frac{π}{{N}_{s}} - ω t - {θ}_{0} ) ] \\ {ψ}_{cdc} ( n , t ) = {n}_{a c} {r}_{g} {l}_{ef} {\int }_{0}^{2 π / {N}_{s}} {B}_{d c}^{n} ( n , θ , t ) d θ = \\ {\sum }_{k = 1 , 3 , 5 …}^{∞} {\sum }_{j = 0 , 1 , 2 …}^{∞} \frac{{n}_{a c} {r}_{g} {l}_{e f} {B}_{m 2}^{{n}_{kj}}}{( k \frac{{N}_{s}}{2} \pm {jN}_{r}^{n} )} sin ( k \frac{π}{2} \pm j \frac{{N}_{r}^{n} π}{{N}_{s}} ) \times \\ sin [ k \frac{π}{2} \pm {jN}_{r}^{n} ( \frac{π}{{N}_{s}} - ω t - {θ}_{0} ) ]\end{matrix}$$
wherein n_{ac} is a number of series turns of each coil, r_{g} is a air gap length, and l_{ef} is a effective axial length;
step 1.5: calculating a back-EMF of each coil through the flux linkage value; wherein a permanent magnet excitation back-EMF e_{cpm} and a field winding excitation back-EMF e_{cdc} are expressed as follows:
$$\{ \begin{matrix}{e}_{cpm} ( t ) = - \frac{d {ψ}_{Apm} ( n , t )}{d t} = {\sum }_{i = 1 , 3 , 5 …}^{∞} {\sum }_{j = 0 , 1 , 2 …}^{∞} \frac{- {jN}_{r}^{n} ω {n}_{a c} {r}_{g} {l}_{ef} {B}_{m 1}^{{n}_{ij}}}{( i \frac{{N}_{s}}{2} \pm {jN}_{r}^{n} )} \times \\ cos ( j \frac{{N}_{r}^{n} π}{{N}_{s}} ) sin [ j {N}_{r}^{n} ( \frac{π}{{N}_{s}} - ω t - {θ}_{0} ) ] \\ {e}_{cdc} ( t ) = - \frac{d {ψ}_{Adc} ( n , t )}{d t} = {\sum }_{k = 1 , 3 , 5 …}^{∞} {\sum }_{j = 0 , 1 , 2 …}^{∞} \frac{- {jN}_{r}^{n} ω {n}_{a c} {r}_{g} {l}_{ef} {B}_{m 2}^{{n}_{kj}}}{( k \frac{{N}_{s}}{2} \pm {jN}_{r}^{n} )} \times \\ cos ( j \frac{{N}_{r}^{n} π}{{N}_{s}} ) sin [ j {N}_{r}^{n} ( \frac{π}{{N}_{s}} - ω t - {θ}_{0} ) ]\end{matrix}$$
wherein ψ_{Apm} is a permanent magnet flux, and ψ_{Adc} is a DC current flux;
step 1.6: according to a back-EMF formula obtained by the previous step, only when j=1, a fundamental component of the back-EMF is generated, generating working harmonics by a 1^{st} permeance harmonics; wherein the fundamental component of the back-EMF E_{cpm} of the permanent magnet excitation and the fundamental component of the back-EMF E_{cdc} of the field winding excitation are expressed as:
$$\{ \begin{matrix}{E}_{cpm} = {\sum }_{i = 1 , 3 , 5 …}^{∞} \frac{- {N}_{r}^{n} ω {n}_{a c} {r}_{g} {l}_{ef} {B}_{m 1}^{{n}_{i 1}}}{( i \frac{{N}_{s}}{2} \pm {N}_{r}^{n} )} cos ( \frac{{N}_{r}^{n} π}{{N}_{s}} ) \\ {E}_{cdc} = {\sum }_{k = 1 , 3 , 5 …}^{∞} \frac{- {N}_{r}^{n} ω {n}_{a c} {r}_{g} {l}_{ef} {B}_{m 2}^{{n}_{k 1}}}{( k \frac{{N}_{s}}{2} \pm {N}_{r}^{n} )} cos ( \frac{{N}_{r}^{n} π}{{N}_{s}} )\end{matrix}$$
wherein ω, n_{ac}, r_{g} and l_{ef} are constant values; in addition, for a fixed number of the split teeth, Bₘ₁ⁿ^{ᵢ₁} and B) are also constant values; by comparing calculation results of the back-EMF E_{cpm} excited by the permanent magnet and the back-EMF E_{cdc} excited by the field winding, the optimal number of the salient poles with the best back-EMF E_{cpm} excited by the permanent magnet and the back-EMF E_{cdc} excited by the field winding are obtained for each split tooth number.

7. The synergy excitation design method of the single winding hybrid excitation magnetic field modulation motor according to claim 5, wherein the specific process of step 2 is:
step 2.1: selecting appropriate value ranges of θₚₘ and θₚₚ, wherein the appropriate value ranges meet the following requirements:
$$\{ \begin{matrix}( n - 1 ) {θ}_{p m} + n {θ}_{tp} \leq 360 / {N}_{s} - 4 \\ {θ}_{c} \geq 4 , {θ}_{p m} > 0 , {θ}_{t p} > 0\end{matrix}$$
wherein θ_{c} is a notch pole arc; in order to ensure a feasibility of a winding assembly process, θ_{c} satisfies a certain angle;
step 2.2: substituting the specific n, θₚₘ and θₜₚ into the magnetomotive force calculation formula to calculate corresponding Fₚₘⁿ and F_{dc}^{nk};
step 2.3: calculating the permanent magnet excitation effective magnetomotive force ΣFₚₘ and the permanent magnet excitation effective magnetomotive force ΣF_{dc} under the specific n, θₚₘ and θₜₚ according to the following formula:
$$\{ \begin{matrix}\sum {F}_{p m} = {\sum }_{{i = 1 , 3 , 5 …}_{j = 1}} {c}_{j} \frac{{N}_{r}^{n}}{m 1} \vert {F}_{p m}^{{n}_{i}} \vert \\ \sum {F}_{d c} = {\sum }_{{k = 1 , 3 , 5 …}_{j = 1}} {c}_{k} \frac{{N}_{r}^{n}}{m 2} \vert {F}_{d c}^{{n}_{k}} \vert\end{matrix}$$
wherein cᵢ represents a positive and negative contribution of the magnetic flux density of m1 order modulated by the magnetomotive force of i^{th} order by the permanent magnet excitation;
when the magnetic flux density is a positive contribution, cᵢ=1; when the magnetic flux density is a negative contribution, cᵢ=−1; cₖ represents a positive and negative contribution of the magnetic flux density of m2 order modulated by the magnetic motiveforce of k^{th} order by the field winding excitation; when the magnetic flux density is a positive contribution, cₖ=1; when the magnetic flux density is a negative contribution, cₖ=−1;
step 2.4: calculating the corresponding ΣFₚₘ and ΣF_{dc} with different n, θₚₘ and θₜₚ according to step 2.3; drawing curves of ΣFₚₘ and ΣF_{dc} with a change of θₚₘ and θₜₚ under the same n; from a variation of the curves, selecting an optimal selection area and optimal structural parameters of θₚₘ and θₜₚ.

8. The synergy excitation design method of the single winding hybrid excitation magnetic field modulation motor according to claim 5, wherein the DC current is the field winding excitation, the motor generates an excitation magnetic field, and the excitation magnetic field enters and leaves an air gap through the split teeth, an effective excitation magnetic flux is formed, an increase of the number of the split teeth n increases the number of the split teeth, the excitation magnetic field increases first and then decreases, and a magnetic flux path of the excitation magnetic field has nothing to do with the number of the split teeth; the permanent magnet generates a permanent magnet magnetic field, the permanent magnet magnetic field forms an effective permanent magnet flux path through the permanent magnet entering and leaving the air gap, the increase in the number of the split teeth increases the number of the permanent magnets, and the effective permanent magnet flux path is independent of the number of split teeth.
